(19) United States
(12) Patent Application Publication
(10) Pub. No.: US 2024/0274663 A1
(43) Pub. Date: Aug. 15, 2024

(54) SEMICONDUCTOR DEVICE

(71) Applicant: FUJI ELECTRIC CO., LTD., Kanagawa (JP)

(72) Inventors: Tohru SHIRAKAWA, Matsumoto-city (JP); Kaname MITSUZUKA, Matsumoto-city (JP)

(21) Appl. No.: 18/641,408

(22) Filed: Apr. 21, 2024

Related U.S. Application Data
(63) Continuation of application No. PCT/JP2023/018390, filed on May 17, 2023.

(30) Foreign Application Priority Data
May 18, 2022 (JP) 2022-081725

(51) Int. Cl. H01L 29/08; H01L 27/06; H01L 29/06; H01L 29/739; H01L 29/861

(52) U.S. Cl. CPC H01L 29/0821; H01L 27/0664; H01L 29/0623; H01L 29/7397; H01L 29/8613

(57) ABSTRACT

Provided is a semiconductor device including: a semiconductor substrate provided with a drift region of a first conductivity type; an emitter region of the first conductivity type provided in contact with an upper surface of the semiconductor substrate and having a higher doping concentration than the drift region; a base region of a second conductivity type provided in contact with the emitter region; a collector region of the second conductivity type provided between the drift region and a lower surface of the semiconductor substrate; and a floating region of the first conductivity type provided in contact with an upper surface of the collector region and having a higher doping concentration than the collector region, wherein the collector region has a first region which is not covered with the floating region and a second region which is covered with the floating region.

The contents of the following patent application(s) are incorporated herein by reference:
NO. 2022-081725 filed in JP on May 18, 2022
NO. PCT/JP2023/018390 filed in WO on May 17, 2023

### BACKGROUND

### 1. Technical Field

The present invention relates to a semiconductor device.

### 2. Related Art

Conventionally, a semiconductor device including an IGBT or the like is known (see, for example, Patent Documents 1 and 2).

### PRIOR ART DOCUMENT

### Patent Document

Patent Document 1: Japanese Patent Application Publication No. 2015-023118
Patent Document 2: Japanese Patent Application Publication No. 2018-049866

### BRIEF DESCRIPTION OF THE DRAWINGS

FIG. 1 illustrates a top view showing an example of a semiconductor device 100 according to one embodiment of the present invention.

FIG. 2 illustrates an enlarged view of a region D in FIG. 1.

FIG. 3 illustrates an example of a cross section e-e in FIG. 2.

FIG. 4A illustrates an exemplary arrangement of first regions 26 and second regions 28 in a top view.

FIG. 4B illustrates characteristics for determining an area S2 of a second region 28 with respect to an area S1 of a first region 26.

FIG. 5 illustrates an exemplary arrangement of first regions 26 and second regions 28 in a top view.

FIG. 6 illustrates an example of a cross section a-a in FIG. 1.

FIG. 7 illustrates another example of the cross section a-a.

FIG. 8 illustrates an exemplary arrangement of emitter regions 12 and contact regions 15 in a top view.

FIG. 9 illustrates another example of the cross section a-a.

FIG. 10 illustrates an exemplary arrangement of emitter regions 12 and contact regions 15 in a top view.

FIG. 11 illustrates an example of a cross section b-b in FIG. 1.

FIG. 12 illustrates an exemplary arrangement of a second region 28-1 in an active portion 160.

FIG. 13 illustrates an example of a net doping concentration distribution on a line c-c in FIG. 3.

FIG. 14 illustrates a relationship between a setting value of a dose amount of a P type impurity implanted into a collector region 22 and a variation in a doping concentration of the collector region 22.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

In the present specification, one side in a direction parallel to a depth direction of a semiconductor substrate is referred to as “upper” and another side is referred to as “lower”. One surface of two principal surfaces of a substrate, a layer or other members is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. Note that the +Z axis direction and the −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including the X axis direction and the Y axis direction.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}−N_{A}. In the present specification, the net doping concentration may be simply described as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. In the present specification, the VOH defect may be referred to as a hydrogen donor.

In the semiconductor substrate in the present specification, bulk donors of the N type are distributed throughout. The bulk donor is a dopant donor substantially uniformly contained in an ingot during the manufacture of the ingot from which the semiconductor substrate is made. The bulk donor in this example is an element other than hydrogen. The bulk donor dopant is, for example, phosphorous, antimony, arsenic, selenium, or sulfur, but the invention is not limited to these. The bulk donor in this example is phosphorous. The bulk donor is also contained in a region of the P type. The semiconductor substrate may be a wafer cut out from a semiconductor ingot, or may be a chip obtained by singulating the wafer. The semiconductor ingot may be manufactured by either a Czochralski method (CZ method), a magnetic field applied Czochralski method (MCZ method), or a float zone method (FZ method). The ingot in this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. In addition, as the semiconductor substrate, a non-doped substrate not containing a dopant such as phosphorous may be used. In that case, the bulk donor concentration (DO) of the non-doped substrate is, for example, from 1×10¹⁰/cm³ or more and to 5×10¹²/cm³ or less. The bulk donor concentration (DO) of the non-doped substrate is preferably 1×10¹¹/cm³ or more. The bulk donor concentration (DO) of the non-doped substrate is preferably 5×10¹²/cm³ or less. Each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, a unit system is the SI base unit system unless otherwise noted. Although a unit of length may be indicated by cm, it may be converted to meters (m) before calculations.

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder (disorder) of a crystal structure due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

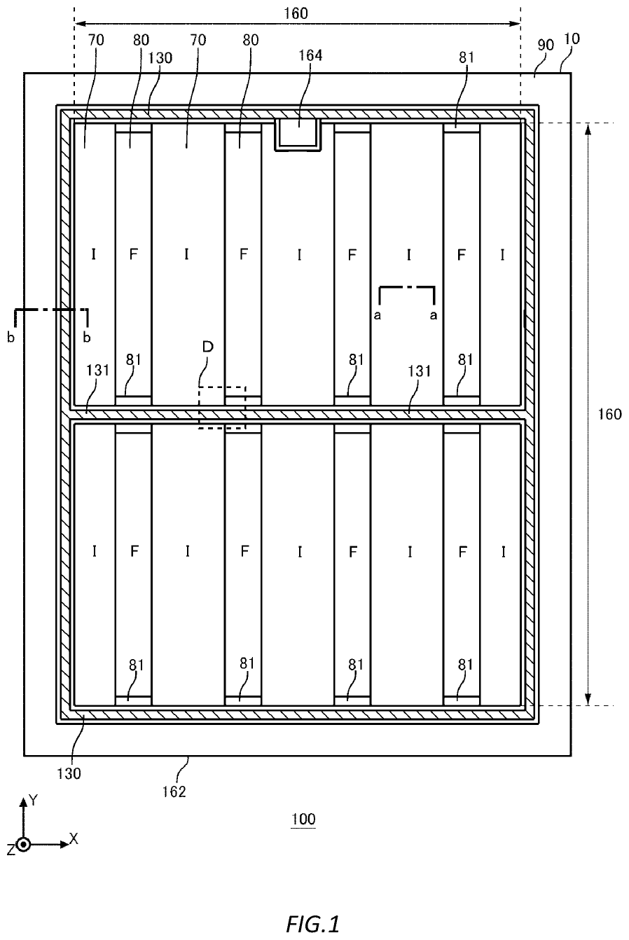

FIG. 1 illustrates a top view showing an example of a semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in a top view. When simply referred to as the top view in the present specification, it means that the semiconductor substrate 10 is viewed from an upper surface side. The semiconductor substrate 10 in this example has two sets of end sides 162 opposite to each other in a top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but is omitted in FIG. 1. The active portion 160 may refer to a region overlapping the emitter electrode in a top view. In addition, a region sandwiched between active portions 160 in a top view may also be included in the active portion 160.

The active portion 160 is provided with a transistor portion 70 including a transistor element such as an insulated gate bipolar transistor (IGBT). The active portion 160 may be further provided with a diode portion 80 including a diode element such as a freewheeling diode (FWD). In the example shown in FIG. 1, transistor portions 70 and diode portions 80 are alternately arranged along a predetermined array direction (the X axis direction in this example) on the upper surface of the semiconductor substrate 10. The semiconductor device 100 in this example is a reverse conduction type IGBT (RC-IGBT).

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in a top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is greater than the width in the X axis direction. Similarly, the length of each of the diode portions 80 in the Y axis direction is greater than the width in the X axis direction. The extending direction of the transistor portion 70 and the diode portion 80, and the longitudinal direction of each trench portion described below may be the same.

Each of the diode portions 80 includes a cathode region of an N+ type in a region in contact with the lower surface of the semiconductor substrate 10. In the present specification, a region where the cathode region is provided is referred to as the diode portion 80. In other words, the diode portion 80 is a region overlapping the cathode region in a top view. On the lower surface of the semiconductor substrate 10, a collector region of a P+ type may be provided in a region other than the cathode region. In the present specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. In addition, in the transistor portion 70, an emitter region of an N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 in this example has a gate pad 164. The semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in a top view. When the semiconductor device 100 is mounted, each pad may be connected to an external circuit via a wiring line such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner in this example has an outer circumferential gate runner 130 and an active-side gate runner 131. The outer circumferential gate runner 130 is arranged between the active portion 160 and the end side 162 of the semiconductor substrate 10 in a top view. The outer circumferential gate runner 130 in this example encloses the active portion 160 in a top view. A region enclosed by the outer circumferential gate runner 130 in a top view may be defined as the active portion 160. In addition, a well region is formed below the gate runner. The well region is a P type region having a higher concentration than the base region described below, and is formed from the upper surface of the semiconductor substrate 10 to a position deeper than that of the base region. A region enclosed by the well region in a top view may be defined as the active portion 160.

The outer circumferential gate runner 130 is connected to the gate pad 164. The outer circumferential gate runner 130 is arranged above the semiconductor substrate 10. The outer circumferential gate runner 130 may be a metal wiring line containing aluminum or the like.

The active-side gate runner 131 is provided in the active portion 160. Providing the active-side gate runner 131 in the active portion 160 can reduce a variation in a wiring line length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a wiring line formed of a semiconductor such as polysilicon doped with an impurity.

The active-side gate runner 131 may be connected to the outer circumferential gate runner 130. The active-side gate runner 131 in this example is provided extending in the X axis direction so as to cross the active portion 160 substantially at the center of the Y axis direction from one outer circumferential gate runner 130 to another outer circumferential gate runner 130 which sandwich the active portion 160. When the active portion 160 is divided by the active-side gate runner 131, the transistor portions 70 and the diode portions 80 may be alternately arranged in the X axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 in this example includes an edge termination structure portion 90 between the active portion 160 and the end side 162 in a top view. The edge termination structure portion 90 in this example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, and a RESURF which are annularly provided enclosing the active portion 160.

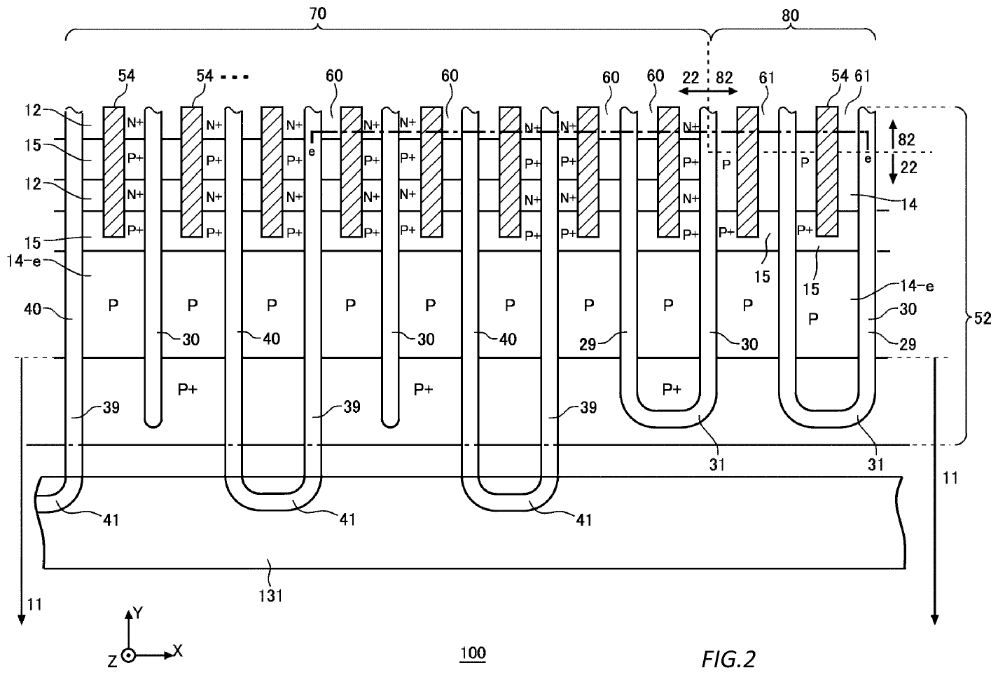

FIG. 2 illustrates an enlarged view of a region D in FIG. 1. The region D is a region including a transistor portion 70, a diode portion 80, and an active-side gate runner 131. A semiconductor device 100 in this example includes a gate trench portion 40, a dummy trench portion 30, a well region 11, an emitter region 12, a base region 14, and a contact region 15 which are provided inside the upper surface side of a semiconductor substrate 10. The gate trench portion 40 and the dummy trench portion 30 each are an example of the trench portion. In addition, the semiconductor device 100 in this example includes an emitter electrode 52 and the active-side gate runner 131 that are provided on or above the upper surface of the semiconductor substrate 10. The emitter electrode 52 and the active-side gate runner 131 are provided in isolation from each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film in this example, a contact hole 54 is provided penetrating the interlayer dielectric film. In FIG. 2, each contact hole 54 is hatched with the diagonal lines.

The emitter electrode 52 is provided above the gate trench portion 40, the dummy trench portion 30, the well region 11, the emitter region 12, the base region 14, and the contact region 15. The emitter electrode 52 is in contact with the emitter region 12, the contact region 15, and the base region 14 at the upper surface of the semiconductor substrate 10, through the contact hole 54. In addition, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portion of the dummy trench portion 30 may not be connected to the emitter electrode 52 and a gate conductive portion, and may be controlled to be at potential different from potential of the emitter electrode 52 and potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided overlapping the active-side gate runner 131. The well region 11 is provided so as to extend with a predetermined width even in a range not overlapping the active-side gate runner 131. The well region 11 in this example is provided away from an end of the contact hole 54 in the Y axis direction toward the active-side gate runner 131 side. The well region 11 is a region of a second conductivity type having a higher doping concentration than the base region 14. The base region 14 in this example is a P− type, and the well region 11 is a P+ type.

Each of the transistor portion 70 and the diode portion 80 includes a plurality of trench portions arrayed in the array direction. In the transistor portion 70 in this example, one or more gate trench portions 40 and one or more dummy trench portions 30 are alternately provided along the array direction. In the diode portion 80 in this example, the plurality of dummy trench portions 30 are provided along the array direction. In the diode portion 80 in this example, the gate trench portion 40 is not provided.

The gate trench portion 40 in this example may have two linear portions 39 extending along the extending direction perpendicular to the array direction (portions of a trench that are linear along the extending direction), and the edge portion 41 connecting the two linear portions 39. The extending direction in FIG. 2 is the Y axis direction.

At least a part of the edge portion 41 is preferably provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the extending direction, or may have linear portions 29 and an edge portion 31 similarly to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom portion in a depth direction of each trench portion is covered with the well region 11 at the end portion in the Y axis direction of each trench portion. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion in this example is provided extending in the extending direction (the Y axis direction) along the trench, at the upper surface of the semiconductor substrate 10. In this example, a mesa portion 60 is provided in the transistor portion 70, and a mesa portion 61 is provided in the diode portion 80. In the case of simply mentioning “mesa portion” in the present specification, the portion refers to each of the mesa portion 60 and the mesa portion 61.

Each mesa portion is provided with the base region 14. In the mesa portion, a region arranged closest to the active-side gate runner 131, in the base region 14 exposed on the upper surface of the semiconductor substrate 10, is defined as a base region 14-e. While FIG. 2 shows the base region 14-e arranged at one end portion of each mesa portion in the extending direction, the base region 14-e is also arranged at another end portion of each mesa portion. Each mesa portion may be provided with at least one of the emitter region 12 of a first conductivity type, and the contact region 15 of the second conductivity type in a region sandwiched between the base regions 14-e in a top view. The emitter region 12 in this example is the N+ type, and the contact region 15 is the P+ type. The emitter region 12 and the contact region 15 may be provided between the base region 14 and the upper surface of the semiconductor substrate 10 in the depth direction.

The mesa portion 60 of the transistor portion 70 has the emitter region 12 in contact with the upper surface of the semiconductor substrate 10 (in other words, exposed on the upper surface). The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to another trench portion in the X axis direction. As an example, contact regions 15 and emitter regions 12 in the mesa portion 60 are alternately arranged along the extending direction of the trench portion (the Y axis direction).

In another example, the contact region 15 and the emitter region 12 in the mesa portion 60 may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base region 14 and the contact region 15 may be provided at an upper surface of the mesa portion 61. In the region sandwiched between the base regions 14-e at the upper surface of the mesa portion 61, the contact region 15 may be provided in contact with each base region 14-e. The base region 14 may be provided in a region sandwiched between the contact regions 15 at the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 in this example is provided above respective regions of the contact region 15, the base region 14, and the emitter region 12. The contact hole 54 is not provided in regions corresponding to the base region 14-e and the well region 11. The contact hole 54 may be arranged at the center of the mesa portion 60 in the array direction (the X axis direction).

In the diode portion 80, a cathode region 82 of the N+ type is provided in a region in direct contact with the lower surface of the semiconductor substrate 10. On the lower surface of the semiconductor substrate 10, a collector region of the P+ type 22 may be provided in a region where the cathode region 82 is not provided. The cathode region 82 and a collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged away from the well region 11 in the Y axis direction. With this configuration, the distance between a region of a P type (the well region 11) having a comparatively high doping concentration and formed up to the deep position, and the cathode region 82 is ensured, so that the breakdown voltage can be improved. The end portion in the Y axis direction of the cathode region 82 in this example is arranged farther away from the well region 11 than the end portion in the Y axis direction of the contact hole 54. In another example, the end portion in the Y axis direction of the cathode region 82 may be arranged between the well region 11 and the contact hole 54.

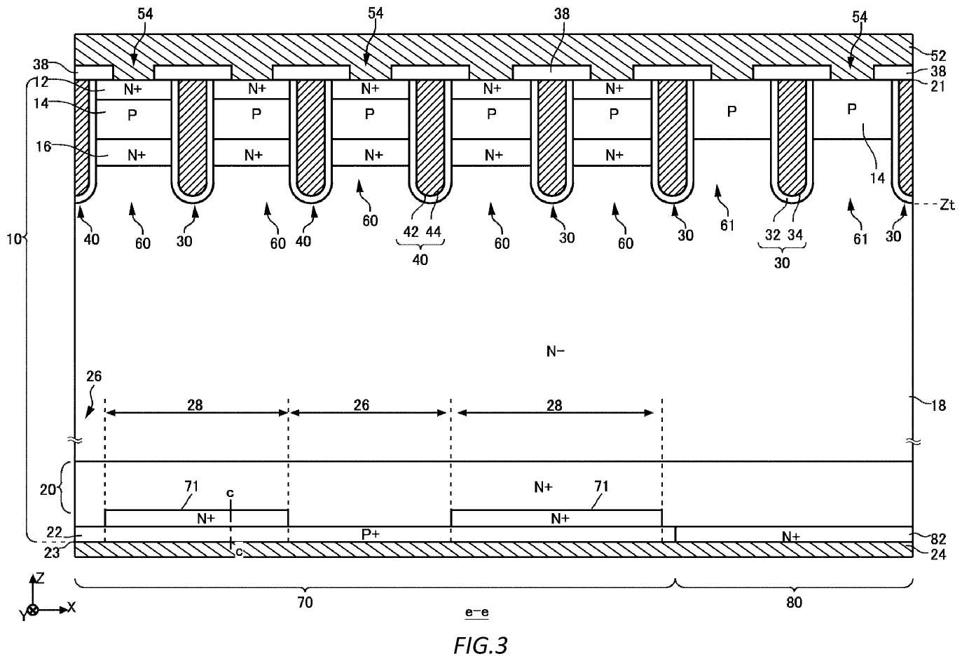

FIG. 3 illustrates an example of a cross section e-e in FIG. 2. The cross section e-e is the XZ plane passing through an emitter region 12 and a cathode region 82. A semiconductor device 100 in this example includes a semiconductor substrate 10, an interlayer dielectric film 38, an emitter electrode 52, and a collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, and other dielectric films. The interlayer dielectric film 38 is provided with a contact hole 54 described with reference to FIG. 2.

The emitter electrode 52 is provided above the interlayer dielectric film 38. The emitter electrode 52 is in contact with an upper surface 21 of the semiconductor substrate 10 through the contact hole 54 of the interlayer dielectric film 38. The collector electrode 24 is provided on a lower surface 23 of the semiconductor substrate 10. The emitter electrode 52 and the collector electrode 24 are formed of a metal material such as aluminum. In the present specification, the direction in which the emitter electrode 52 is connected to the collector electrode 24 (the Z axis direction) is referred to as a depth direction.

The semiconductor substrate 10 includes a drift region 18 of an N type or an N− type. The drift region 18 is provided in each of a transistor portion 70 and a diode portion 80.

In a mesa portion 60 of the transistor portion 70, the emitter region 12 of an N+ type and a base region 14 of a P− type are provided in order from an upper surface 21 side of the semiconductor substrate 10. The drift region 18 is provided below the base region 14. The mesa portion 60 may be provided with an accumulation region 16 of the N+ type. The accumulation region 16 is arranged between the base region 14 and the drift region 18. The accumulation region 16 is a region of the N+ type having a higher doping concentration than the drift region 18. Providing the accumulation region 16 having a high concentration between the drift region 18 and the base region 14 can increase a carrier implantation enhancement effect (IE effect) and reduce an on-voltage. The accumulation region 16 may be provided so as to cover the entire lower surface of the base region 14 in each mesa portion 60. The accumulation region 16 may be provided or may not be provided in each mesa portion 61 of the diode portion 80 as well.

The emitter region 12 is exposed on the upper surface 21 of the semiconductor substrate 10 and is provided in contact with a gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 in this example is provided in contact with the emitter region 12. The base region 14 may be in contact with the trench portions on both sides of the mesa portion 60.

A mesa portion 61 of the diode portion 80 is provided with the base region 14 of the P− type in contact with the upper surface 21 of the semiconductor substrate 10. The drift region 18 is provided below the base region 14. The base region 14 of the diode portion 80 may be referred to as an anode region.

In each of the transistor portion 70 and the diode portion 80, a buffer region 20 of the N+ type may be provided below the drift region 18. The doping concentration of the buffer region 20 is higher than the doping concentration of the drift region 18. The buffer region 20 may have a concentration peak having a higher doping concentration than the doping concentration of the drift region 18. The doping concentration of the concentration peak refers to a doping concentration at the local maximum of the concentration peak. In addition, as the doping concentration of the drift region 18, an average value of doping concentrations in the region where the doping concentration distribution is substantially flat may be used.

The buffer region 20 in this example may have two or more concentration peaks in the depth direction (the Z axis direction) of the semiconductor substrate 10. The concentration peak of the buffer region 20 may be provided at the same depth position as, for example, a chemical concentration peak of hydrogen (a proton) or phosphorous. The buffer region 20 may function as a field stopper layer which prevents a depletion layer expanding from the lower end of the base region 14 from reaching the collector region 22 of a P+ type and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. Note that an element serving as a donor and an acceptor in each region is not limited to the example described above. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion is provided from the upper surface 21 of the semiconductor substrate 10 to a region below the base region 14, penetrating the base region 14. In a region where at least any one of the emitter region 12, a contact region 15, and the accumulation region is provided, each trench portion also penetrates these doping regions. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

As described above, the transistor portion 70 is provided with the gate trench portion 40 and a dummy trench portion 30. In the diode portion 80, the dummy trench portion 30 is provided, and the gate trench portion 40 is not provided. The boundary in the X axis direction between the diode portion 80 and the transistor portion 70 in this example is the boundary between the cathode region 82 and the collector region 22.

The gate trench portion 40 includes a gate trench provided in the upper surface 21 of the semiconductor substrate 10, a gate dielectric film 42, and a gate conductive portion 44. The gate dielectric film 42 is provided covering the inner wall of the gate trench. The gate dielectric film 42 may be formed by oxidizing or nitriding a semiconductor on the inner wall of the gate trench. The gate conductive portion 44 is provided farther inward than the gate dielectric film 42 in the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided in the dummy trench, and is provided farther inward than the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 in this example are covered with the interlayer dielectric film 38 on the upper surface 21 of the semiconductor substrate 10. Note that the bottom portions of the dummy trench portion 30 and the gate trench portion 40 may be formed in a curved-surface shape (a curved shape in the cross section) convexly downward. In the present specification, a depth position of a lower end of the gate trench portion 40 is represented by Zt.

In the semiconductor device 100, a switching loss is preferably low. Especially when the semiconductor device 100 is used in a high-speed operation product having an operating frequency of 20 kHz or more, the switching loss of the semiconductor device 100 may become a dominant loss in the product. Therefore, for example if the turn-off loss Eoff of the semiconductor device 100 is low, the product loss can be lowered.

Lowering implantation efficiency of carriers of the collector region 22 can decrease the turn-off loss Eoff. On the other hand, lowering the implantation efficiency of the collector region 22 increases a proportion of a variation to a design value of the implantation efficiency of the collector region 22, and increases a characteristic variation among individual semiconductor devices 100 or lots.

For example, although decreasing a doping concentration of the collector region 22 can lower the implantation efficiency, a proportion of a variation to a design value of the doping concentration of the collector region 22 increases. In such a case, a variation in sheet resistance of the collector region 22 increases. When the variation in the sheet resistance of the collector region 22 increases, variations in on-voltage and latch-up withstand capability of the semiconductor device 100, or the like increase. In addition, in a circuit which uses a plurality of semiconductor devices 100 in parallel, variations in on-voltages of the semiconductor devices 100 may cause current concentration on a specific device to decrease withstand capability of the circuit.

The semiconductor device 100 in this example includes a floating region 71 of the N+ type provided in contact with an upper surface of the collector region 22 and having a higher doping concentration than the collector region 22. The floating region 71 and the collector region 22 form a PN junction. The buffer region 20 may be provided on the floating region 71. The floating region 71 may not be or may be provided on the cathode region 82.

The floating region 71 is provided on part of the upper surface of the collector region 22. The collector region 22 has a first region 26 which is not covered with the floating region 71 and a second region 28 which is covered with the floating region 71. First regions 26 and second regions 28 in this example are alternately arranged alongside in the XY plane. One transistor portion 70 may include two or more first regions 26 and two or more second regions 28. The first region 26 may be provided or the second region 28 may be provided, at an end portion of the transistor portion 70 in the X axis direction. Although an upper surface of each of the first region 26 and the second region 28 is in contact with the buffer region 20 in this example, the upper surface may alternatively be in contact with the drift region 18.

Covering part of the collector region 22 with the floating region 71 can lower the implantation efficiency of the carriers (holes in this example) implanted into the drift region 18 without lowering the doping concentration of the collector region 22. Therefore, it is possible to decrease the turn-off loss Eoff while suppressing a variation in the doping concentration of the collector region 22. The implantation efficiency is as follows. For example, a current density of holes is represented by Jₚ, and a current density of electrons is represented by Jₙ. The implantation efficiency of the collector region 22 is a ratio of a current density of minority carriers to a total current density. In this example, since the conductivity type of the drift region 18 is the N type and the conductivity type of the collector region 22 is a P type, the minority carriers of the drift region 18 are holes. In this case, the implantation efficiency in the collector region 22 can be defined by the following expression:

$${J}_{p} / ( {J}_{p} + {J}_{n} )$$

Implantation efficiency η₂ of the second region 28 when implantation efficiency η₁ of the first region 26 is set to 1 can be defined by Expression 1.

$${η}_{1} = 1$$

$${η}_{2} = ( {N}_{A} / ( {N}_{A} + {N}_{D} ) ) \times ( {W}_{P} / ( {W}_{N} + {W}_{P} ) ) … \qquad Expression 1$$

Note that N_{A} is the doping concentration of the collector region 22, N_{D} is a doping concentration of the floating region 71, W_{P} is a thickness of the collector region 22 in the Z axis direction, and W_{N} is a thickness of the floating region 71 in the Z axis direction. As the doping concentration of each region, a peak value in the region may be used, or an average value may be used. When the doping concentration in each region has a peak, a thickness of a region of a full width at half maximum of the peak may be used as the thickness of each region.

Providing the second region 28 having comparatively low implantation efficiency can decrease overall implantation efficiency of the collector region 22. Accordingly, the turn-off loss Eoff of the semiconductor device 100 can be reduced. In addition, since the implantation efficiency of the first region 26 is comparatively high, a variation in the implantation efficiency of the first region 26 can be decreased. Regarding the implantation efficiency of the collector region 22, since the implantation efficiency of the first region 26 becomes dominant, decreasing the variation in the implantation efficiency of the first region 26 can suppress a variation in the overall implantation efficiency of the collector region 22.

A doping concentration N_{D} (a net doping concentration) of the floating region 71 may be 1.5 times or more, may be twice or more, may be five times or more, may be 10 times or more, or may be 20 times or more a doping concentration N_{A} (a net doping concentration) of the collector region 22. As the doping concentration N_{D} of the floating region 71 becomes higher, the implantation efficiency of the second region 28 can become lower. As an example, the doping concentration N_{D} may be 1×10¹⁷/cm³ or more, or may be 1×10¹⁸/cm³ or more. The doping concentration N_{D} may be 1×10²⁰/cm³ or less, or may be 1×10¹⁹/cm³ or less. The doping concentration N_{A} may be 1×10¹⁶/cm³ or more, or may be 1×10¹⁷/cm³ or more. The doping concentration N_{A} may be 1×10¹⁹/cm³ or less, or may be 1×10¹⁸/cm³ or less.

A thickness W_{N} of the floating region 71 in the depth direction (the Z axis direction) may be 0.1 times or more, may be 0.5 times or more, may be greater than one time, or may be twice or more a thickness W_{P} of the collector region 22 in the depth direction. As the floating region 71 becomes thicker, the implantation efficiency of the second region 28 can become lower. As an example, the thickness W_{N} may be 0.1 μm or more, or may be 0.3 μm or more. The thickness W_{N} may be 1.0 μm or less, or may be 0.5 μm or less. The thickness Wₚ may be 0.1 μm or more, or may be 0.2 μm or more. The thickness W_{P} may be 1.0 μm or less, or may be 0.5 μm or less.

A product N_{D}×W_{N} as a product of the doping concentration N_{D} and the thickness W_{N} of the floating region 71 may be 1.5 times or more, may be twice or more, may be five times or more, may be 10 times or more, or may be 20 times or more a product N_{A}×Wₚ as a product of the doping concentration N_{A} of the collector region 22 and the thickness Wₚ. As the product N_{D}×W_{N} becomes greater, the implantation efficiency of the second region 28 can become lower.

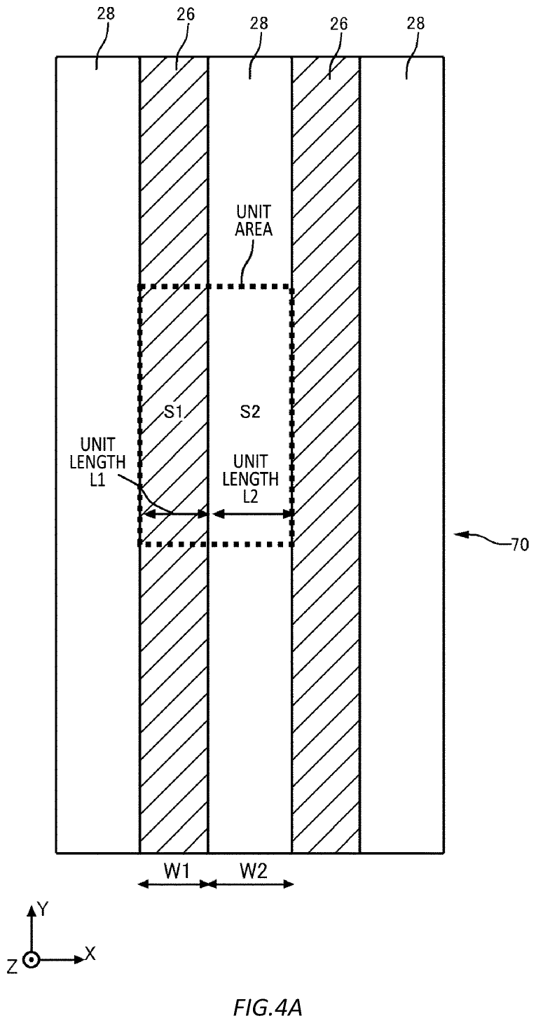

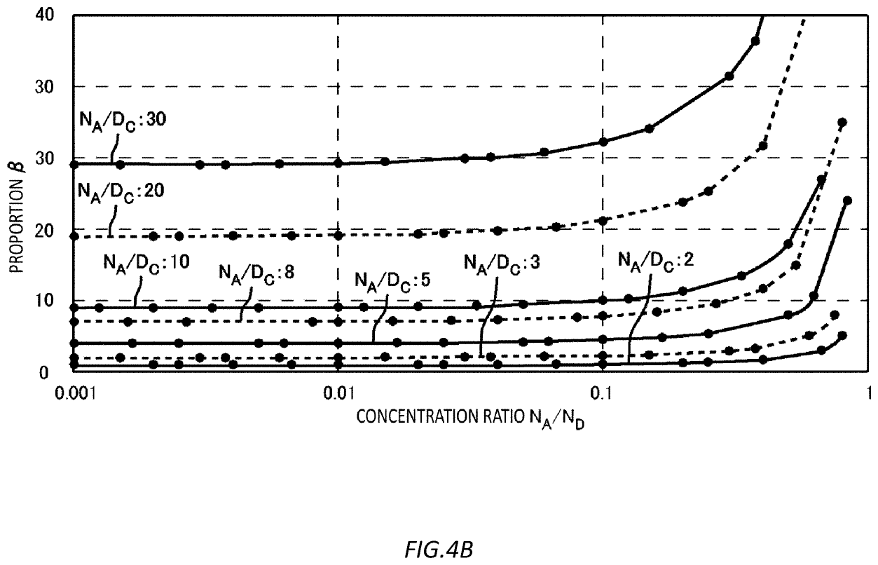

FIG. 4A illustrates an exemplary arrangement of first regions 26 and second regions 28 in a top view. FIG. 4A shows part of a transistor portion 70. An area of a first region 26 and an area of a second region 28 which occupy a unit area of a collector region 22 are respectively represented by S1 and S2. Although the unit area in FIG. 4A is part of the collector region 22, the unit area may be the entire collector region 22. In this case, a total area of the first regions 26 and a total area of the second regions 28 in a semiconductor device 100 may be respectively represented by S1 and S2.

With implantation efficiency of the first region 26 being represented by η₁ and with implantation efficiency of the second region 28 being represented by η₂ (η₁>η₂), average implantation efficiency η_{c} is defined by Expression 2.

$${η}_{C} = ( {S}_{1} \times {η}_{1} + {S}_{2} \times {η}_{2} ) / ( {S}_{1} + {S}_{2} ) … \qquad Expression 2$$

The average implantation efficiency η_{c} is 0.1 or more and 0.4 or less. Accordingly, the average implantation efficiency η_{c} of the semiconductor device 100 can be sufficiently lowered to reduce a turn-off loss. The average implantation efficiency η_{c} may be 0.15 or more, or may be 0.2 or more. The average implantation efficiency η_{c} may be 0.35 or less, or may be 0.3 or less. Implantation efficiency is a ratio of a current density of minority carriers to a total current density as described above, and in this example, a ratio of a current density of holes to the total current density. In a conduction state, excessive minority carriers and majority carriers are accumulated in a drift region 18, causing conductivity modulation. When a proportion of the current density of the minority carriers is within a range described above, a concentration of minority carriers on a collector region 22 side accumulated in the drift region 18 becomes lower, and a concentration of minority carriers on an emitter region 12 side can be relatively increased. Accordingly, the turn-off loss can be reduced. When the average implantation efficiency η_{c} is 0.5 or more, the turn-off loss comparatively increases. Therefore, the average implantation efficiency η_{c} may be at least less than 0.5.

The implantation efficiency η₂ may be 0.3 or less. Accordingly, the average implantation efficiency η_{c} can be decreased to reduce a switching loss of the semiconductor device 100. The implantation efficiency η₂ may be 0.5 times or less the implantation efficiency η₁.

The area S1 of the first region 26 may be the same as or different from the area S2 of the second region 28. The area S1 may be smaller than the area S2. This makes it easier to decrease the average implantation efficiency η_{c} and an average doping concentration D_{C} to be described below and reduce the turn-off loss. The area S1 may be 80% or less, or may be 50% or less of the area S2. Here, the average implantation efficiency η_{c} may be determined from Expression 2 for a unit area as shown in FIG. 4A. When the first regions 26 and the second regions 28 are distributed in a striped pattern, a unit length L1 of the first region 26 and a unit length L2 of the second region 28 in a distribution direction (the X axis direction in FIG. 4A) may be respectively substituted for S1 in Expression 2 and S2 in Expression 2 for calculation.

As shown in FIG. 4A, the first regions 26 and the second regions 28 may be each arranged in a striped pattern with a longitudinal length in the Y axis direction. A length of the first region 26 in the Y axis direction may be the same as or different from a length of the second region 28 in the Y axis direction. The first regions 26 and the second regions 28 in this example are alternately arranged in the X axis direction. A width W1 of the first region 26 in the X axis direction may be the same as or different from a width W2 of the second region 28 in the X axis direction. The width W1 may be smaller than the width W2. This makes it easier to decrease the average implantation efficiency η_{c} and reduce the turn-off loss. The width W1 may be 80% or less, or may be 50% or less of the width W2.

FIG. 4B illustrates characteristics for determining the area S2 of the second region 28 with respect to the area S1 of the first region 26. A horizontal axis represents a proportion of a doping concentration N_{A} of the collector region 22 to a doping concentration N_{D} of a floating region 71, and a vertical axis represents a proportion β to be described below. FIG. 4B shows seven characteristics for cases where ratios of the doping concentration N_{A} of the collector region 22 to the average doping concentration D_{C} to be described below (N_{A}/D_{C}) are 30, 20, 10, 8, 5, 3, and 2.

With an effective doping concentration of the collector region 22 in the second region 28 being represented by D₂, the average doping concentration D_{C} is defined by Expression 3A.

$${D}_{C} = ( {S}_{1} \times {N}_{A} + {S}_{2} \times {D}_{2} ) / ( {S}_{1} + {S}_{2} ) … \qquad Expression 3 A$$

Here, the effective doping concentration of the collector region 22 in the second region 28 is defined not as an actual doping concentration of the collector region 22, but as a doping concentration of the collector region 22 assumed not to substantially function as the collector region 22 due to the floating region 71. That is, since the effective doping concentration D₂ of the collector region 22 in the second region 28 is substantially 0, it may be considered that D₂=0 in Expression 3A. That is,

$${D}_{C} = {S}_{1} \times {N}_{A} / ( {S}_{1} + {S}_{2} ) … . \qquad Expression 3 B$$

A doping concentration D₁ of the collector region 22 in the first region 26 may be higher than the average doping concentration D_{C}. A proportion of the area S2 of the second region 28 to the area S1 of the first region 26 in the collector region 22 is represented by a. The proportion α is given by the following expression:

$$α = {S}_{2} / {S}_{1} … \qquad Expression 4$$

Here, the proportion β is defined by the following expression:

$$β = ( {N}_{A} / {D}_{C} - 1 ) \times {N}_{D} / ( {N}_{D} - {N}_{A} ) … \qquad Expression 5$$

The proportion 3 is an index which allows estimation of how many times the area S2 of the second region 28 should be equal to or greater than the area S1 of the first region 26 in order to obtain a desired average doping concentration D_{C}, when the doping concentration of the collector region 22 of the first region 26 is N_{A} and the doping concentration of the floating region 71 of the second region 28 is N_{D}. The proportion a is smaller than the proportion 1.

A first term on a right side of Expression 5 is a term indicating at least how many times the area S2 of the second region 28 should be of the area S1 of the first region 26. A second term on the right side is a correction term corresponding to the doping concentration N_{A} of the collector region 22 of the first region 26 and the doping concentration N_{D} of the floating region 71 of the second region 28. When the doping concentration N_{D} of the floating region 71 is sufficiently higher than the doping concentration N_{A} of the collector region 22, the second term is substantially 1. As a value of the doping concentration N_{D} of the floating region 71 is closer to that of the doping concentration N_{A} of the collector region 22, the area S2 of the second region 28 must be set greater in order to obtain a target average doping concentration D_{C}.

As shown in FIG. 4B, if the doping concentration N_{D} of the floating region 71 is sufficiently higher than the doping concentration N_{A} of the collector region 22, the proportion 1 stabilizes without substantially depending on a proportion of the doping concentration N_{A} of the collector region 22 to the average doping concentration D_{C}. Stabilization of the proportion 1 suppresses fluctuation or variation in the average doping concentration D_{C} and stabilizes an on-voltage is stabilized. The doping concentration N_{A} of the collector region 22 may be 0.1 times or less, may be 0.6 times or less, may be 0.4 times or less, may be 0.2 times or less, or may be 0.01 times or less the doping concentration N_{D} of the floating region 71. The doping concentration N_{A} of the collector region 22 may be 10⁻⁵ times or more, may be 10⁻⁴ times or more, may be 0.001 times or more, or may be 0.01 times or more the doping concentration N_{D} of the floating region 71.

The doping concentration N_{A} of the collector region 22 may be higher than the average doping concentration D_{C}, or may be 1.5 times or more, twice or more, three times or more, or five times or more the average doping concentration D_{C}. The doping concentration N_{A} of the collector region 22 may be 30 times or less, may be 20 times or less, or may be 10 times or less the average doping concentration D_{C}.

Here, the average doping concentration D_{C} may be determined from Expression 3B for a unit area as shown in FIG. 4A. When the first regions 26 and the second regions 28 are distributed in a striped pattern, the unit length L1 of the first region 26 and the unit length L2 of the second region 28 in the distribution direction (the X axis direction in FIG. 4A) may be respectively substituted for S1 in Expression 3B and S2 in Expression 3B for calculation.

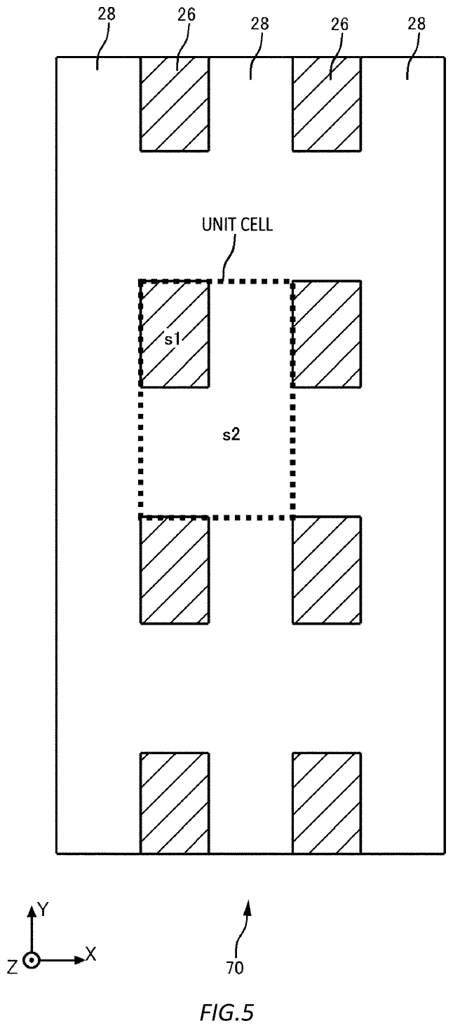

FIG. 5 illustrates an exemplary arrangement of first regions 26 and second regions 28 in a top view. This example is different from the example shown in FIG. 4A in that the first regions 26 are discretely arranged in the Y axis direction as well. Other structures are similar to those in the example shown in FIG. 4A. A first region 26 and a second region 28 in this example have a configuration in which a collector region 22 is regularly lined with unit cells (or unit lattices) including a cell (or a unit lattice) indicated by a dotted line. An average doping concentration D_{C} in this example may be determined from Expression 3A or 3B. With an area of the first region 26 in a unit cell being represented by s1 and with an area of the second region 28 in the unit cell being represented by s2, an area S1 of the first region 26 and an area S2 of the second region 28 in Expression 3A or 3B may be respectively substituted for s1 and s2 for calculation.

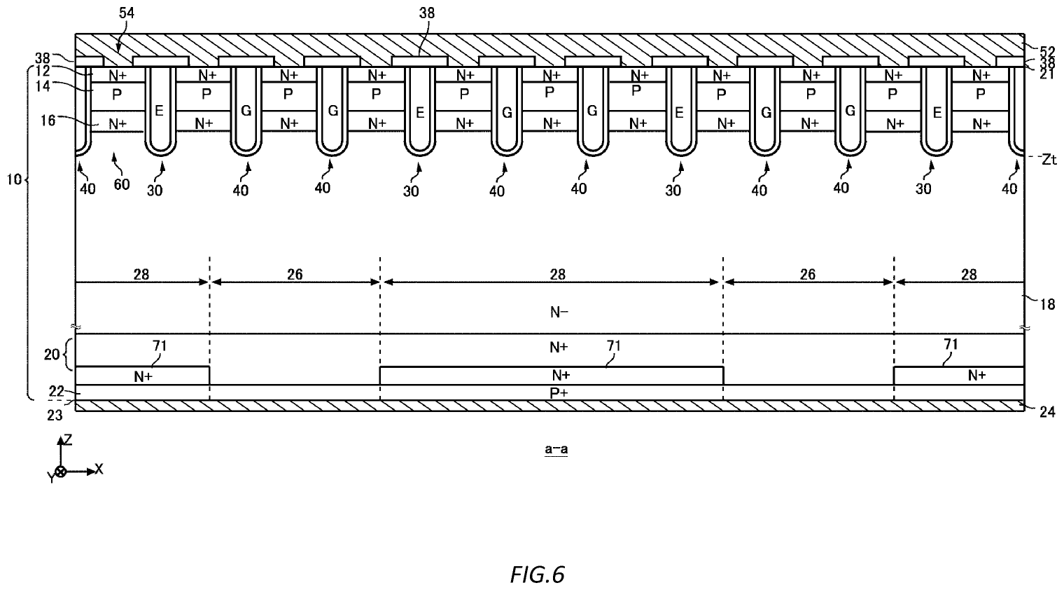

FIG. 6 illustrates an example of a cross section a-a in FIG. 1. The cross section a-a is the XZ plane passing through a transistor portion 70. FIG. 6 shows an exemplary arrangement of first regions 26 and second regions 28 in the X axis direction. Structures other than the first regions 26 and the second regions 28 are similar to those of the examples described with reference to FIGS. 1 to 5.

In this example, at least one first region 26 is provided at a position overlapping a gate trench portion 40. All the first regions 26 may be respectively provided at positions overlapping gate trench portions 40. A first region 26 overlapping a gate trench portion 40 means that at least one gate trench portion 40 is arranged within a range where the first region 26 is provided in the X axis direction. The first region 26 may overlap a dummy trench portion 30 as well. Arranging the first region 26 below the gate trench portion 40 can increase a carrier density below a gate structure to reduce an on-voltage. The number of gate trench portions 40 to be arranged above one first region 26 may be greater than the number of gate trench portions 40 to be arranged above one second region 28. Accordingly, an overall on-voltage of the transistor portion 70 can be reduced. The number of gate trench portions 40 to be arranged above one first region 26 may be the same as or smaller than the number of gate trench portions 40 to be arranged above one second region 28.

As shown in FIG. 6, a second region 28 may be provided below at least one gate trench portion 40. The second region 28 may be provided below each of dummy trench portions 30. The second regions 28 may be respectively provided below all the dummy trench portions 30, or the first region 26 may be provided below at least one dummy trench portion 30.

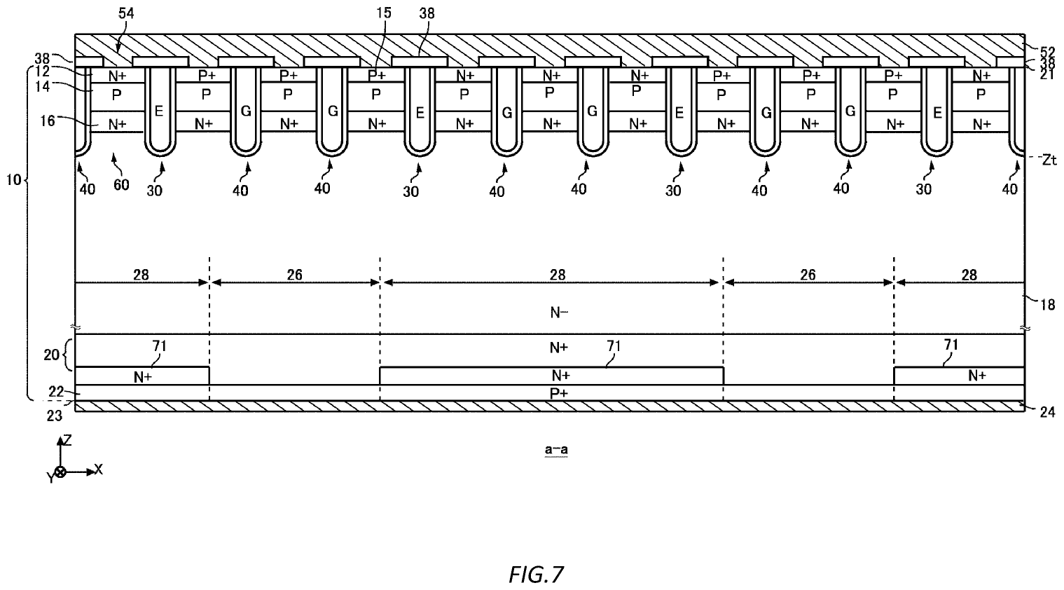

FIG. 7 illustrates another example of the cross section a-a. In this example, arrangement of contact regions 15 at an upper surface 21 of a semiconductor substrate 10 is different from that in the example shown in FIG. 6. Other structures are similar to those in the example shown in FIG. 6. A contact region 15 is a region of a P+ type provided in contact with the upper surface 21 of the semiconductor substrate 10 and having a higher doping concentration than a base region 14.

Either an emitter region 12 or the contact region 15 is exposed on an upper surface of a mesa portion 60 in this example. In this example, more contact regions 15 are arranged for a first region 26 than for a second region 28. This makes it easier to extract holes implanted from the first region 26 via the contact region 15, allowing suppression of decrease in latch-up withstand capability.

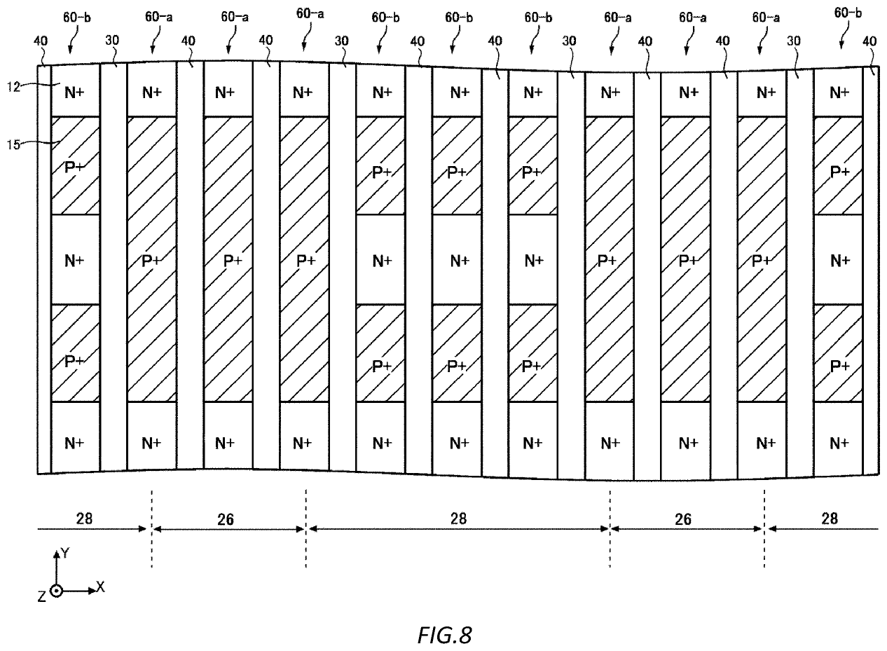

FIG. 8 illustrates an exemplary arrangement of emitter regions 12 and contact regions 15 in a top view. In FIG. 8, the contact regions 15 are hatched with diagonal lines. At an upper surface of each mesa portion 60 in this example, the emitter regions 12 and the contact regions 15 are alternately arranged in the Y axis direction. A proportion S_{C}/S_{R} of an area S_{C} of the contact regions 15 exposed on an upper surface 21 of a semiconductor substrate 10 to a unit area S_{R} is defined as a contact area ratio. The unit area S_{R} may be an area of the entire upper surface of one mesa portion 60. A contact area ratio R1 in a first region 26 may be higher than a contact area ratio R2 in a second region 28. A contact area ratio in each region may be a contact area ratio in a region overlapping each region in a top view. Accordingly, resistance of a path through which holes implanted from the first region 26 are extracted to an emitter electrode 52 can be lowered, and latch-up can be suppressed. The contact area ratio R1 may be 1.2 times or more, may be 1.5 times or more, or may be twice or more the contact area ratio R2.

In this example, a length in the Y axis direction of one contact region 15 in the first region 26 is greater than a length in the Y axis direction of one contact region 15 in the second region 28. A length in the Y axis direction of an emitter region 12 in the first region 26 may be the same as or different from a length in the Y axis direction of an emitter region 12 in the second region 28. In another example, a length in the Y axis direction of one emitter region 12 in the first region 26 may be smaller than a length in the Y axis direction of one emitter region 12 in the second region 28. In this case, a length in the Y axis direction of a contact region 15 in the first region 26 may be the same as or different from a length in the Y axis direction of a contact region 15 in the second region 28.

In this example, a mesa portion 60 which overlaps the first region 26 is defined as a mesa portion 60-a, and a mesa portion 60 which does not overlap the first region 26 is defined as a mesa portion 60-b. A mesa portion 60 which overlaps both the first region 26 and the second region 28 may also be defined as the mesa portion 60-a. A contact area ratio in the mesa portion 60-a may be defined as the contact area ratio in the first region 26. A contact area ratio in the mesa portion 60-b may be defined as the contact area ratio in the second region 28.

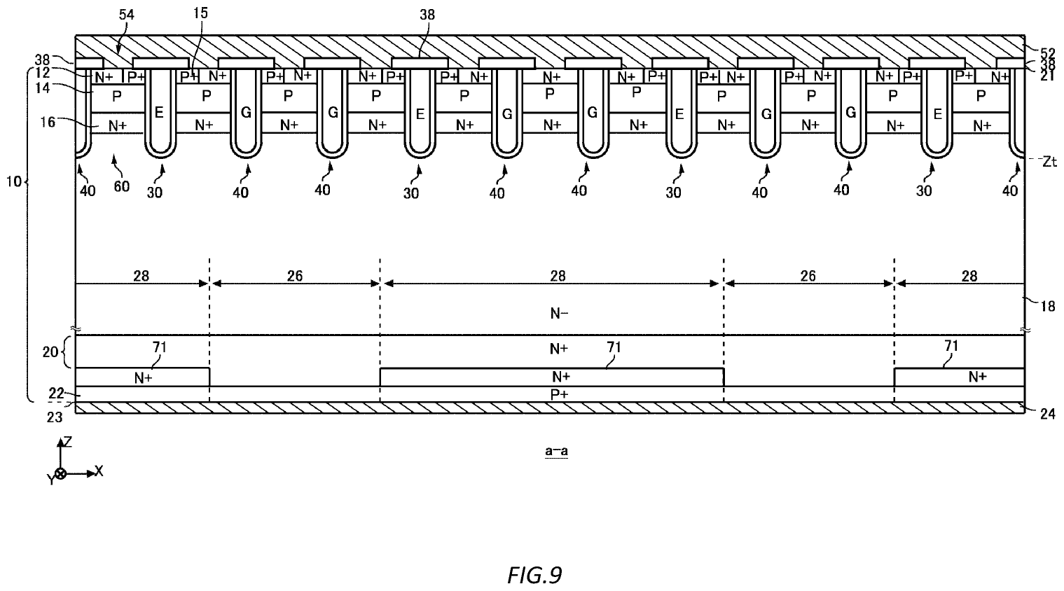

FIG. 9 illustrates another example of the cross section a-a. In this example, arrangement of contact regions 15 at an upper surface 21 of a semiconductor substrate 10 is different from that in the example shown in FIG. 7. Other structures are similar to those in the example shown in FIG. 7. The contact region 15 in this example is arranged alongside of an emitter region 12 in the X axis direction.

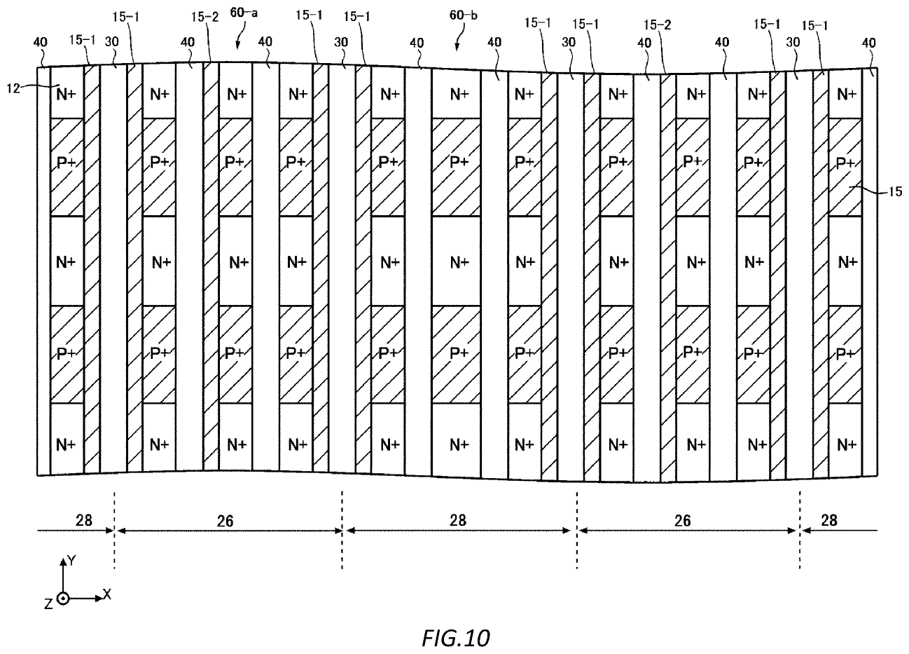

FIG. 10 illustrates an exemplary arrangement of emitter regions 12 and contact regions 15 in a top view. In FIG. 10, the contact regions 15 are hatched with diagonal lines. At an upper surface of each mesa portion 60 in this example, a contact region 15 in direct contact with an emitter region 12 in the X axis direction is arranged being connected to a contact region 15 in direct contact with an emitter region 12 in the Y axis direction. Also In this example, a contact area ratio R1 in a first region 26 is higher than a contact area ratio R2 in a second region 28. In addition, arranging the contact region 15 in direct contact with the emitter region 12 forms, next to the emitter region 12, a path through which holes implanted from the first region 26 are extracted to an emitter electrode 52, so that resistance of the path can be lowered, and latch-up can be suppressed. The contact area ratio R1 may be 1.2 times or more, may be 1.5 times or more, or may be twice or more the contact area ratio R2. The contact regions 15 as well as contact regions 15-1 and contact regions 15-2 hatched with diagonal lines may have the same doping concentration distribution.

A semiconductor device 100 may have a contact region 15-2 in contact with a gate trench portion 40 and a contact region 15-1 in contact with a dummy trench portion 30. In this example, contact regions 15-1 are arranged on both sides of each dummy trench portion 30 in the X axis direction.

An area ratio of the contact region 15-2 provided in the first region 26 (an area of the contact region 15-2 with respect to an area of the first region 26) is higher than an area ratio of the contact region 15-2 provided in the second region 28. In this example, one contact region 15-2 is provided for at least one gate trench portion 40 in the first region 26, and the contact region 15-2 is not provided in the second region 28.

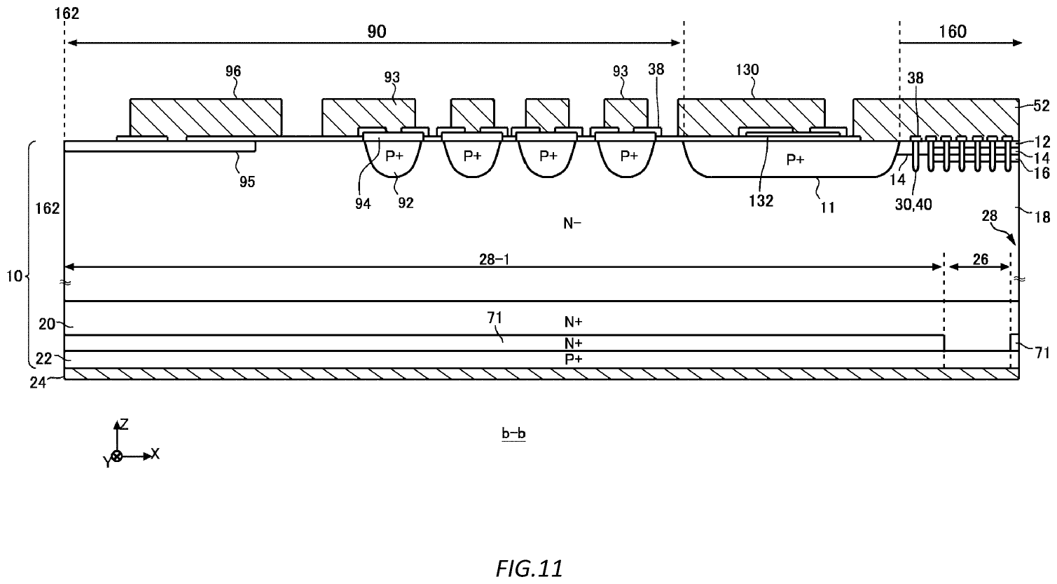

FIG. 11 illustrates an example of a cross section b-b in FIG. 1. The cross section b-b is the XZ plane passing through an edge termination structure portion 90 and part of an active portion 160 (a transistor portion 70). The edge termination structure portion 90 may include one or more guard rings 92. The edge termination structure portion 90 may include one or more field plates 93. A guard ring 92 is a region of a P+ type provided in contact with an upper surface 21 of a semiconductor substrate 10. The guard ring 92 encloses the active portion 160. A field plate 93 is a metal member arranged above the upper surface 21 of the semiconductor substrate 10. An interlayer dielectric film 38 may be provided between the field plate 93 and the semiconductor substrate 10. The field plate 93 and the guard ring 92 may be or may not be electrically connected to each other. In this example, the field plate 93 and the guard ring 92 are connected to each other via a wiring line 94 made of polysilicon and provided on the upper surface of the semiconductor substrate 10.

A channel stopper 95 and an electrode 96 may be provided in a part farther outward than the guard ring 92 and the field plate 93. The channel stopper 95 prevents a depletion layer extending from the active portion 160 from reaching an end side 162 of the semiconductor substrate 10. The channel stopper 95 is a region of a P type or an N type having a higher concentration than the drift region 18. The electrode 96 is connected to the channel stopper 95. The same potential as that of a collector electrode 24 may be applied to the electrode 96.

An outer circumferential gate runner 130 is provided between the active portion 160 and the edge termination structure portion 90. A gate runner 132 made of polysilicon may be provided between the outer circumferential gate runner 130 and the semiconductor substrate 10. A well region 11 is provided below the outer circumferential gate runner 130 and the gate runner 132. The well region 11 may be connected to an emitter electrode 52. The well region 11 may be in contact with a base region 14.

The active portion 160 is provided with both a first region 26 and a second region 28. The edge termination structure portion 90 may be provided with the second region 28 and may not be provided with the first region 26. Providing the second region 28 in the entire edge termination structure portion 90 can decrease implantation efficiency of holes implanted into the edge termination structure portion 90 and improve a dynamic breakdown voltage of the edge termination structure portion 90. Accordingly, overvoltage withstand capability (clamp withstand capability) of a semiconductor device 100 can be improved.

A second region 28-1 in the edge termination structure portion 90 may extend to a region below the well region 11. The second region 28-1 may overlap the entire well region 11. In other words, the second region 28-1 may be provided and the first region 26 may not be provided, at a position overlapping the well region 11. The second region 28-1 may extend to a position overlapping the emitter electrode 52. The second region 28-1 may extend to the active portion 160. In this example, an end portion of the semiconductor substrate 10 on a side opposite to the end side 162 is defined as an end portion of the active portion 160. Extending the second region 28-1 makes it easier to improve a breakdown voltage in the edge termination structure portion 90.

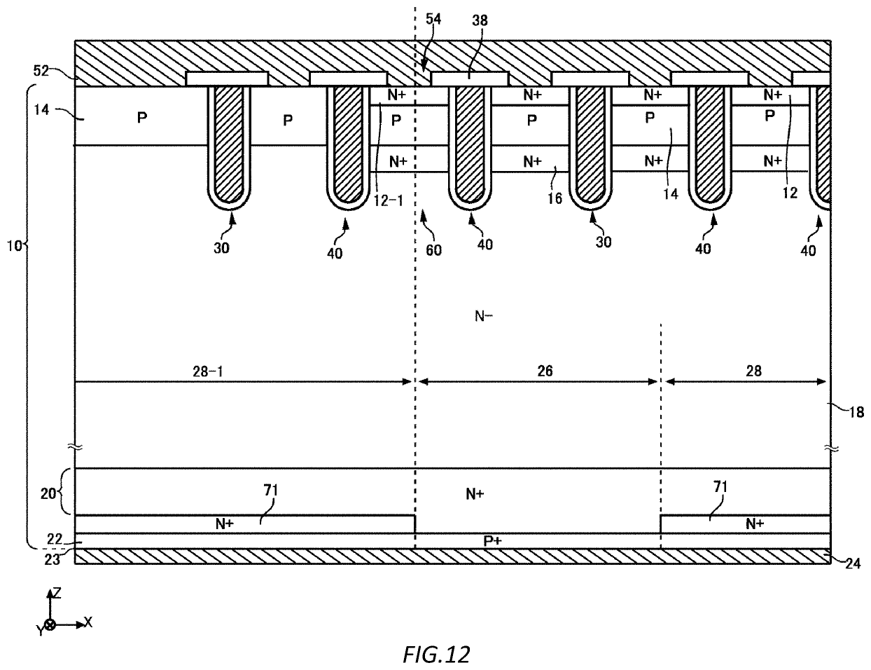

FIG. 12 illustrates an exemplary arrangement of a second region 28-1 in an active portion 160. FIG. 12 illustrates an enlarged view of a vicinity of an end portion of the second region 28-1 on an active portion 160 side. The second region 28-1 in this example is provided extending to a position overlapping an emitter region 12-1 of the active portion 160. The emitter region 12-1 in this example is an emitter region 12 closest to an edge termination structure portion 90 in the X axis direction. An end portion of the second region 28-1 in the X axis direction may overlap the emitter region 12-1. The end portion of the second region 28-1 in the X axis direction may be provided at a position overlapping a contact hole 54 of a mesa portion 60 provided with the emitter region 12-1. A boundary between a first region 26 and the second region 28-1 may be provided below the mesa portion 60. The configurations as shown in FIGS. 11 and 12 can suppress a characteristic variation of a transistor portion 70 and reduce a turn-off loss while improving a breakdown voltage of the edge termination structure portion 90.

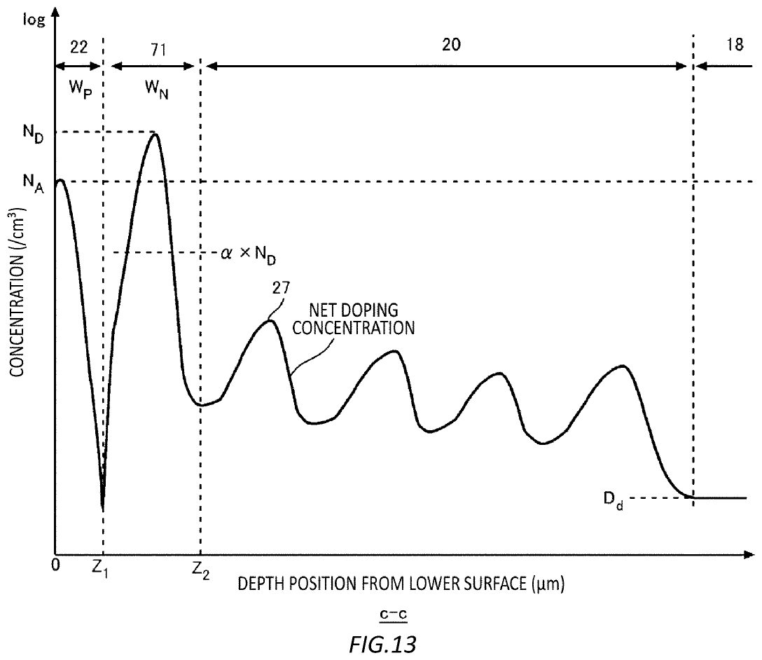

FIG. 13 illustrates an example of a net doping concentration distribution on a line c-c in FIG. 3. The line c-c passes through part of a collector region 22, a floating region 71, a buffer region 20, and a drift region 18 in a second region 28. A doping concentration of the buffer region 20 is higher than a doping concentration D_{d} of the drift region 18. The buffer region 20 in this example has one or more doping concentration peaks 27 arranged at different positions in a depth direction. A doping concentration N_{D} of the floating region 71 may be higher than the doping concentration of the buffer region 20. The doping concentration N_{D} of the floating region 71 may be higher than any of the doping concentration peaks 27 of the buffer region 20. The doping concentration N_{D} of the floating region 71 may be at 10 times or more, may be at 50 times or more, or may be at 100 times or more a maximum value of the doping concentration in the buffer region 20.

A lower end position and an upper end position of the floating region 71 are respectively represented by Z₁ and Z₂. The lower end position Z₁ may be a depth position of a PN junction portion between a collector region 22 and the buffer region 20. The upper end position Z₂ may be a position at which the doping concentration first becomes at a local minimum value above a position at which the doping concentration becomes at a peak value N_{D}. In another example, a position at which the doping concentration first becomes at α×N_{D} above the position at which the doping concentration becomes at the peak value N_{D}, may be defined as the upper end position Z₂. α is a real number from 0 to 1. For example, α may be 0.5, may be 0.1, or may be 0.01. In addition, a position at which the doping concentration first becomes at α×N_{D} below the position at which the doping concentration is at the peak value N_{D}, may be defined as the lower end position Z₁.

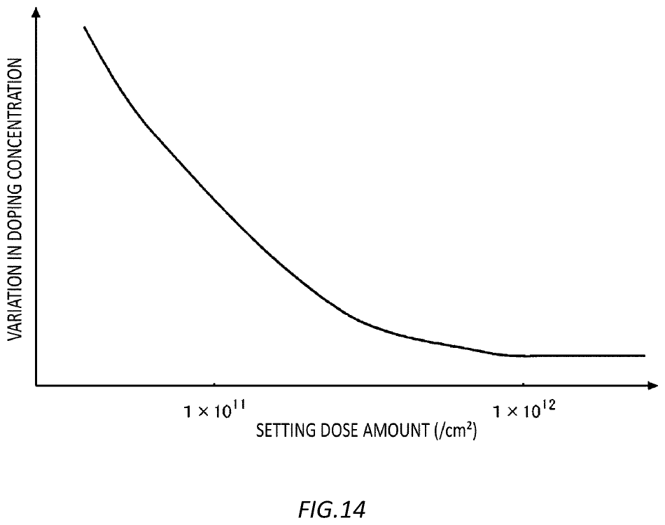

FIG. 14 illustrates a relationship between a setting value of a dose amount of a P type impurity implanted into a collector region 22 and a variation in a doping concentration of the collector region 22. The doping concentration of the collector region 22 is at a value obtained after the P type impurity is implanted and annealing is performed. The variation in the doping concentration may be a standard deviation of doping concentrations in a plurality of semiconductor devices 100. Although the variation in the doping concentration is shown in the example shown in FIG. 14, an on-voltage of a semiconductor device 100 similarly varies.

Even when a certain dose amount is set, the doping concentration varies due to a variation in the dose amount, a variation in an annealing condition, or the like. Decreasing the setting value of the dose amount increases a proportion of the variation. Therefore, as shown in FIG. 14, the variation in the doping concentration tends to become greater as the setting value of the dose amount becomes smaller. In the example shown in FIG. 14, the variation in the doping concentration becomes substantially constant when the setting value of the dose amount exceeds 1×10¹²/cm².

The dose amount for the collector region 22 may be 1×10¹²/cm² or more. A value obtained by integrating a peak waveform of the doping concentration of the collector region 22 over a range of a full width at half maximum in a depth direction may be used as the dose amount for the collector region 22. The dose amount for the collector region 22 may be 1×10¹³/cm² or more, or may be 1×10¹⁴/cm² or more.

While the present invention has been described by way of the embodiments, the technical scope of the present invention is not limited to the above described embodiments. It is apparent to persons skilled in the art that various alterations or improvements can be made to the above described embodiments. It is apparent from the description of the claims that embodiments added with such alterations or improvements can also be included in the technical scope of the present invention.

Note that the operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

What is claimed is:

1. A semiconductor device comprising:
a semiconductor substrate having an upper surface and a lower surface and provided with a drift region of a first conductivity type;
an emitter region of the first conductivity type provided in contact with the upper surface of the semiconductor substrate and having a higher doping concentration than the drift region;
a base region of a second conductivity type provided in contact with the emitter region;
a collector region of the second conductivity type provided between the drift region and the lower surface of the semiconductor substrate; and
a floating region of the first conductivity type provided in contact with an upper surface of the collector region and having a higher doping concentration than the collector region, wherein
the collector region has a first region which is not covered with the floating region and a second region which is covered with the floating region.

2. The semiconductor device according to claim 1, wherein
a doping concentration of the floating region is 10 times or more a doping concentration of the collector region.

3. The semiconductor device according to claim 1, wherein
a thickness of the floating region in a depth direction is 0.5 times or more a thickness of the collector region in the depth direction.

4. The semiconductor device according to claim 1, wherein
a product of a doping concentration and a thickness in a depth direction of the floating region is 10 times or more a product of a doping concentration and a thickness in the depth direction of the collector region.

5. The semiconductor device according to claim 1, comprising a transistor portion, wherein
when an area of the first region and an area of the second region which occupy the collector region in a top view of the transistor portion are respectively represented by S1 and S₂, implantation efficiency of the first region is represented by η₁, and the implantation efficiency of the second region is represented by η₂, average implantation efficiency η_{c} given by a following expression is 0.1 or more and 0.4 or less:
$${η}_{C} = ( {S}_{1} \times {η}_{1} + {S}_{2} \times {η}_{2} ) / ( {S}_{1} + {S}_{2} ) .$$

6. The semiconductor device according to claim 1, further comprising a buffer region formed between the collector region and the drift region and having a higher doping concentration than the drift region, wherein
the floating region is arranged between the buffer region and the collector region, and
a doping concentration of the floating region is higher than a doping concentration of the buffer region.

7. The semiconductor device according to claim 3, comprising a transistor portion, wherein
when an area of the first region and an area of the second region which occupy the collector region in a top view of the transistor portion are respectively represented by S₁ and S₂,
an average doping concentration D_{C} of the collector region is given by a following expression by using a doping concentration N_{A} of the collector region in the first region:
$${D}_{C} = {S}_{1} \times {N}_{A} / ( {S}_{1} + {S}_{2} ) ,$$
the doping concentration N_{A} of the collector region in the first region is higher than the average doping concentration D_{C},
a proportion α of the area S₂ of the second region to the area S₁ of the first region is given by a following expression:
$$α = {S}_{2} / {S}_{1} ,$$
a proportion β is given by a following expression including a doping concentration N_{D} of the floating region:
$$β = ( {N}_{A} / {D}_{C} - 1 ) \times {N}_{D} / ( {N}_{D} - {N}_{A} ) ,$$
and
the doping concentration N_{A} of the collector region in the first region is 10⁻⁵ times or more and 0.6 times or less the doping concentration N_{D} of the floating region.

8. The semiconductor device according to claim 1, wherein
a plurality of gate trench portions are arranged along an array direction, each of the plurality of gate trench portions being a gate trench portion provided from the upper surface of the semiconductor substrate to the drift region and in contact with the emitter region and the base region, and
one or more first regions including the first region and one or more second regions including the second region are alternately arranged along the array direction.

9. The semiconductor device according to claim 1, comprising:
an active portion including the emitter region and the base region;
a well region of the second conductivity type enclosing the active portion in a top view and provided in contact with the upper surface of the semiconductor substrate; and
an edge termination structure portion arranged between the well region and an end side of the semiconductor substrate, wherein
the active portion is provided with both the first region and the second region, and
the edge termination structure portion is provided with the second region and is not provided with the first region.

10. The semiconductor device according to claim 9, wherein
the second region is provided and the first region is not provided, at a position overlapping the well region.

11. The semiconductor device according to claim 9, wherein
the second region of the edge termination structure portion is provided extending to a position overlapping the emitter region of the active portion.

12. The semiconductor device according to claim 1, further comprising a gate trench portion provided from the upper surface of the semiconductor substrate to the drift region and in contact with the emitter region and the base region, wherein
the first region is provided at a position overlapping the gate trench portion.

13. The semiconductor device according to claim 1, further comprising:
a trench portion provided from the upper surface of the semiconductor substrate to the drift region and in contact with the emitter region and the base region, wherein a plurality of trench portions, each of which is the trench portion, are arranged along an array direction;
one or more mesa portions which are regions sandwiched between the trench portions in the array direction, inside the semiconductor substrate; and
a contact region provided in contact with the upper surface of the semiconductor substrate and having a higher doping concentration than the base region, wherein
a contact area ratio in the first region is higher than a contact area ratio in the second region, and
the contact area ratio is a proportion of an area of the contact region exposed on an upper surface of one mesa portion of the one or more mesa portions to an area of the one mesa portion.

14. The semiconductor device according to claim 12, comprising a plurality of gate trench portions including the gate trench portion, wherein
the first region is arranged at a position overlapping the plurality of gate trench portions.

15. The semiconductor device according to claim 12, further comprising:
an emitter electrode provided on or above the upper surface of the semiconductor substrate; and
a dummy trench portion provided from the upper surface of the semiconductor substrate to the drift region, in contact with the emitter region and the base region, and electrically connected to the emitter electrode, wherein
the second region is provided at a position overlapping the dummy trench portion.

16. The semiconductor device according to claim 12, wherein
the collector region has a plurality of first regions including the first region, and
all of the first regions are arranged at the position overlapping the gate trench portion.

17. The semiconductor device according to claim 5, wherein
the implantation efficiency η₁ of the first region and the implantation efficiency η₂ of the second region are ratios of a current density of minority carriers to a total current density.

18. The semiconductor device according to claim 5, comprising a transistor portion, wherein
in the transistor portion,
at least one of a plurality of first regions including the first region or a plurality of second regions including the second region are repeatedly arranged along a repetition direction, and a width of at least one of the plurality of first regions or the plurality of second regions repeatedly arranged in the repetition direction is equal to a repetition pitch.

19. The semiconductor device according to claim 2, wherein
a plurality of gate trench portions are arranged along an array direction, each of the plurality of gate trench portions being a gate trench portion provided from the upper surface of the semiconductor substrate to the drift region and in contact with the emitter region and the base region, and
one or more first regions including the first region and one or more second regions including the second region are alternately arranged along the array direction.

20. The semiconductor device according to claim 3, wherein
a plurality of gate trench portions are arranged along an array direction, each of the plurality of gate trench portions being a gate trench portion provided from the upper surface of the semiconductor substrate to the drift region and in contact with the emitter region and the base region, and
one or more first regions including the first region and one or more second regions including the second region are alternately arranged along the array direction.
